(19) United States
(12) Patent Application Publication
(10) Pub. No.: US 2012/0005818 A1
(43) Pub. Date: Jan. 12, 2012

(54) SOLAR POWERED HOT TUB

(76) Inventor: Nathanael S. Coelho, Fort Wayne, IN (US)

(21) Appl. No.: 12/833,122

(22) Filed: Jul. 9, 2010

(51) Int. Cl. E04H 4/00; E04H 4/14; H02J 3/00; H01L 31/042; H02J 1/10; E04H 4/06; E04H 4/12

(52) U.S. Cl. 4/493; 4/498; 4/506; 136/244; 307/43; 307/80

(57) ABSTRACT

A hot tub includes a shell defining a water compartment, at least one electrical component, and a cover positionable over the shell. The cover includes a body and an integral solar panel mounted to the body. The solar panel provides electrical output power to one or more of the electrical components.

### BACKGROUND OF THE INVENTION

1. Field of the Invention

The present invention relates to heated spas, and, more particularly, to covers for such spas.

2. Description of the Related Art

Conventional heated hot tubs, also known as spas, provide certain health benefits to users. Such hot tubs include primary benefits of soft tissue massage, increased pulmonary circulation, and increased relaxation. Hot tubs may be constructed as structures which are set into an elevated platform or floor. Hot tubs for home use are typically constructed as stand-alone units which may be set on a concrete pad or the like at a selected location. The hot tub shell itself is typically vacuum formed to a desired shape, and a plurality of holes are formed in the shell to receive a number of differently configured jets. The shell is supported on a frame, which also supports insulated sidewalls and a floor. The electronics, pumps, heaters, and plumbing are all positioned within the frame, out of view behind the sidewalls. For a conventionally configured hot tub as described above, the vacuum formed shell typically is formed with a number of predefined upright seats, each accommodating a different user during operation.

With ever increasing energy costs, there is more incentive to use “green” energy alternatives, such as solar or wind power. Moreover, there are also certain tax incentives for using different types of solar or wind power. One type of green energy uses a solar panel and/or wind turbine which are placed on top of a home, and provide electrical energy to a bank of batteries for providing DC or inverted AC power to connected electrical loads.

Luxury items such as hot tubs may become less desirable to own and operate because of increasing energy costs. The resistance heater(s) which are used within the hot tub to maintain the water at an elevated temperature can consume large amounts of electrical energy. Moreover, the high flow rate pumps which are used for massage therapy during operation can also at least briefly consume large amounts of power. For this reason, a 50 or 60 amp ground fault circuit interrupter (GFCI) is typically used to provide electrical power to the hot tub. Given that most electrical distribution panels within a home are equipped with a 200 amp main breaker, a 50 or 60 amp GFCI box for powering a hot tub can be a significant load on the home electrical network.

What is needed in the art is a hot tub which is more energy efficient.

### SUMMARY OF THE INVENTION

The present invention provides a hot tub with a cover having an integral solar panel. The solar panel is used to power at least low power consumption components, or alternatively any selected electrical components. A controller switches the otherwise solar powered components to grid power when the integral power collection system is depleted due to low light conditions for a period of time.

The invention in one form is directed to a hot tub including a shell defining a water compartment, at least one electrical component, and a cover positionable over the shell. The cover includes a body and an integral solar panel mounted to the body. The solar panel provides electrical output power to one or more of the electrical components.

The invention in another form is directed to a cover for a hot tub having a plurality of electrical components therein. The cover includes a body and a solar panel integrally mounted to an upper surface of the body. The solar panel has an output cable which is configured to provide electrical power to at least one of the electrical components within the hot tub.

### BRIEF DESCRIPTION OF THE DRAWINGS

The above-mentioned and other features and advantages of this invention, and the manner of attaining them, will become more apparent and the invention will be better understood by reference to the following description of an embodiment of the invention taken in conjunction with the accompanying drawings, wherein:

FIG. 1 is a perspective view of an embodiment of a spa of the present invention;

FIG. 2 is a top view of the cover shown on the spa of FIG. 1;

FIG. 3 is a side sectional view taken along line 3-3 in FIG. 2; and

FIG. 4 is an electrical schematic of the spa shown in FIG. 1.

Corresponding reference characters indicate corresponding parts throughout the several views. The exemplification set out herein illustrates an embodiment of the invention, in one form, and such exemplification is not to be construed as limiting the scope of the invention in any manner.

### DETAILED DESCRIPTION OF THE INVENTION

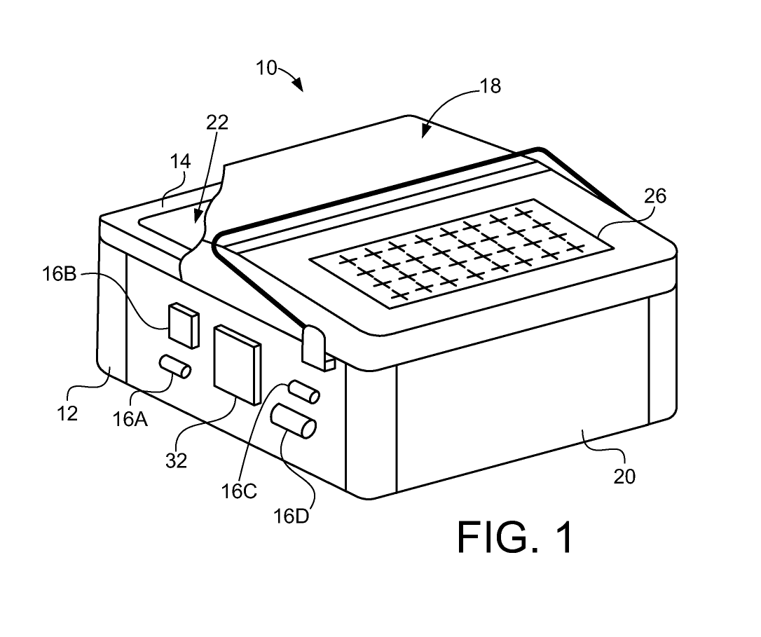

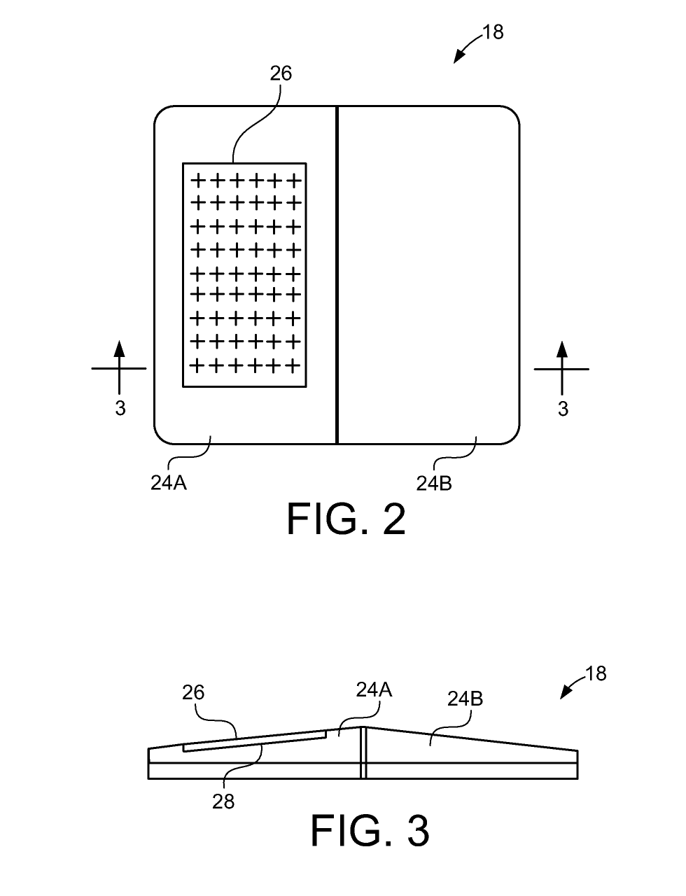

Referring now to the drawings, and more particularly to FIGS. 1-3, there is shown a hot tub 10 (also known as a spa 10) which generally includes a frame 12, shell 14, a plurality of electrical components 16 and a cover 18. Skirting panels 20 are removably attached to frame 12 to provide access to the interior of frame 12.

Shell 14 defines a water compartment 22 into which a user may enter after removal of cover 18. Shell 14 may be a single compartment as shown, or may include multiple compartments, depending on the configuration. Shell 14 typically is formed with a plurality of holes into which are fitted a plurality of corresponding jets (not shown). In the illustrated embodiment, shell 14 and frame 12 are separate components forming part of hot tub 10. However, for certain applications, it is possible that shell 14 may define an integral frame with side walls for hot tub 10.

The plurality of electrical components 16 maintained within frame 12 and behind skirting panels 20 may include a number of known components, which generally can be divided into two categories; namely, low power consumption components and high power consumption components. The low power consumption components include one or more low flow rate circulation (circ) pumps 16A and an ozonator 16B. The high power consumption components include one or more resistance heaters 16C and one or more high flow rate pumps 16D used for water jet therapy (the electric and fluid lines interconnecting the electrical components 16A-16D are not shown in FIG. 1 for simplicity sake).

Cover 18 cover is positionable over shell 14, and includes a body 24 and an integral solar panel 26 mounted to body 24. Solar panel 26 provides electrical output power to one or more of the electrical components 16. Body 24 includes a cutout 28, and solar panel 26 is recessed within cutout 28. Preferably, solar panel 26 is generally flush with the upper surface of body 24 when recessed within the cutout 28, but could also extend slightly above the upper surface of body 24.

In the illustrated embodiment, cover body 24 has a plurality of panels 24A and 24B which are hinged together, and solar panel 26 is mounted to a single panel 24A. Solar panel 26 is mounted to panel 24A in a manner so as not to interfere with folding of hinged panels 24A and 24B together, one on top of another. It will be appreciated that for certain applications, it may be desirable to mount more than one solar panel 26 to cover 18. For example, with a cover 18 having a pair of hinged panels 24A and 24B, it may be desirable to mount one solar panel 26 to panel 24A and another solar panel 26 to panel 24B. Alternatively, it may be desirable to mount more than one solar panel 26 to the same panel 24A or 24B.

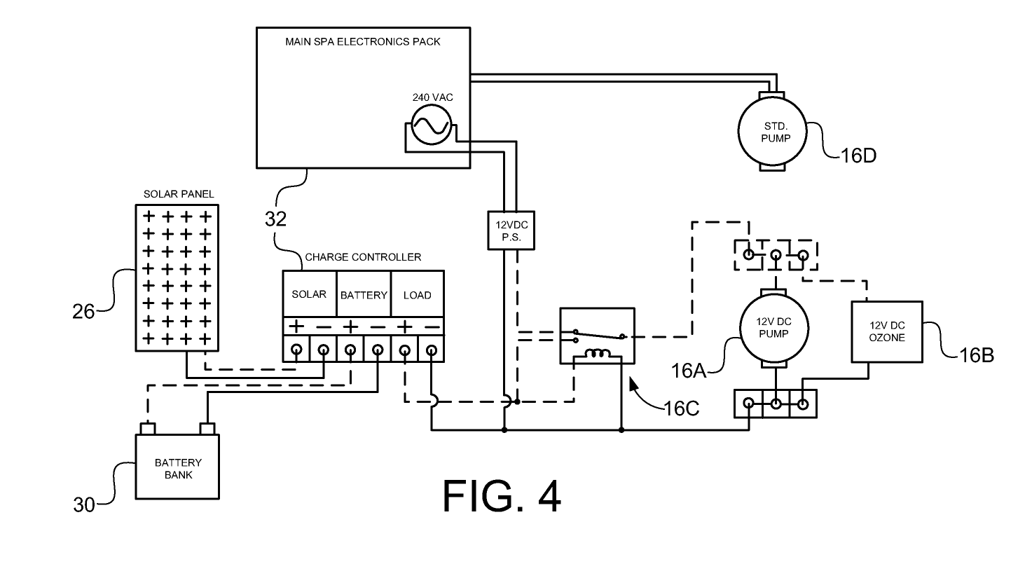

Also positioned within frame 12 is a battery bank 30 (shown schematically in FIG. 4 as a single battery) which is coupled with solar panel 26. Battery bank 30 indirectly connects solar panel 26 with one or more of the electrical components 16.

A controller 32 is connected with each of solar panel 26, battery bank 30 and at least one electrical component 16 (FIGS. 1 and 4). Controller 32 is configured to power the at least one electrical component either from battery bank 30 or grid power, dependent upon a charge state of battery bank 30.

When hot tub 10 is not being used, and cover 18 is in an unfolded state on top of shell 14, solar radiation impinges upon solar panel 26 and causes solar panel 26 to provide a low amperage output charge to battery bank 30. Solar panel 26 is preferably sized and configured to charge battery bank 30 with approximately 2-4 hours of direct sunlight per day. Battery bank 30 is preferably sized and configured to provide approximately 72 hours of power when in a fully charged state, assuming that battery bank 30 is used to power a circ pump and an ozonator. Controller 32 is coupled with and detects the charge level of battery bank 30, and uses battery bank 30 unless the charge state falls below a predetermined charge state. In the event that the charge state of battery bank 30 falls below the threshold level, then controller 32 switches the input power used to power the circ pump and ozonator from the battery bank 30 to grid power.

When hot tub 10 is in use, the cover 18 is folded back and to a side of frame 12. Solar panel 26 need not be disabled during use, but also will not provide an output charge to battery bank 30 since the cover panel 24B is folded over the active surface of solar panel 26.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A hot tub, comprising:
a shell defining a water compartment;
at least one electrical component; and
a cover positionable over said shell, said cover including a body and an integral solar panel mounted to said body, said solar panel providing electrical output power to at least one said electrical component.

2. The hot tub of claim 1, wherein said cover body has a cutout, and said solar panel is recessed within said cutout.

3. The hot tub of claim 1, wherein said cover body has a plurality of panels hinged together, and said solar panel is mounted to one of said panels.

4. The hot tub of claim 3, wherein said solar panel is mounted to said one panel in a manner so as not to interfere with folding of said hinged panels together, one on top of another.

5. The hot tub of claim 1, wherein said at least one electrical component includes a plurality of electrical components segregated into low power consumption components and high power consumption components, said solar panel providing electrical output power to said low power consumption components.

6. The hot tub of claim 5, wherein said low power consumption components include at least one circulation pump and an ozonator.

7. The hot tub of claim 6, wherein said high power consumption components include at least one resistance heater and at least one high flow rate pump.

8. The hot tub of claim 1, including a battery bank coupled with said solar panel, said battery bank indirectly connecting said solar panel with said at least one said electrical component.

9. The hot tub of claim 8, further including a controller connected with each of said solar panel, said battery bank and said at least one said electrical component, said controller configured to power said at least one said electrical component either from said battery bank or grid power, dependent upon a charge state of said battery bank.

10. The hot tub of claim 1, including a frame carrying said shell.

11. A cover for a hot tub having a plurality of electrical components therein, comprising:
a body; and
a solar panel integrally mounted to an upper surface of said body, said solar panel having an output cable which is configured to provide electrical power to at least one of the electrical components within the hot tub.

12. The cover of claim 11, wherein said body has a cutout, and said solar panel is recessed within said cutout.

13. The cover of claim 11, wherein said body has a plurality of panels hinged together, and said solar panel is mounted to one of said panels.

14. The hot tub of claim 13, wherein said solar panel is mounted to said one panel in a manner so as not to interfere with folding of said hinged panels together, one on top of another.
